(19) United States
(12) Patent Application Publication
(10) Pub. No.: US 2011/0249534 A1
(43) Pub. Date: Oct. 13, 2011

(54) PACKAGE MANUFACTURING METHOD, PIEZOELECTRIC VIBRATOR MANUFACTURING METHOD, OSCILLATOR, ELECTRONIC DEVICE, AND RADIO-CONTROLLED TIMEPIECE

(76) Inventors: Junya Fukuda, Chiba-shi (JP); Masashi NUMATA, Chiba-shi (JP); Sumihiko KURITA, Chiba-shi (JP)

(21) Appl. No.: 13/166,381

(22) Filed: Jun. 22, 2011

Related U.S. Application Data
(63) Continuation of application No. PCT/JP2009/053329, filed on Feb. 25, 2009.

(51) Int. Cl. H01L 41/22; H03B 5/36; G04C 11/02; C03B 11/00

(52) U.S. Cl. 368/47; 29/25.35; 65/104; 331/158

(57) ABSTRACT

A package manufacturing method of the present invention is a method of manufacturing a package with a recessed cavity formed in at least one of first and second substrates formed of a glass material and includes a cavity forming step of forming the cavity by performing press molding on at least one molded substrate of the first and second substrates and a heat treatment step of heating the molded substrate formed with the cavity.

### RELATED APPLICATIONS

This application is a continuation of PCT/JP2009/053329 filed on Feb. 25, 2009. The entire content of this application is incorporated herein by reference.

### BACKGROUND OF THE INVENTION

1. Field of the Invention

The present invention relates to a package manufacturing method, a piezoelectric vibrator manufacturing method, an oscillator, an electronic device, and a radio-controlled timepiece.

2. Description of the Related Art

In recent years, piezoelectric vibrators using crystal or the like have been used in mobile phones or portable information terminals as a time source, a timing source of a control signal or the like, a reference signal source, and the like. Various piezoelectric vibrators are known as such kinds of piezoelectric vibrators, and a surface mount type piezoelectric vibrator is known as one type of piezoelectric vibrator. As this type of piezoelectric vibrator, a two-layer structure type piezoelectric vibrator is generally known in which a piezoelectric vibrating reed is mounted in a cavity formed in a package configured to include a base substrate and a lid substrate (for example, refer to Patent Citation 1). This packaged two-layer structure type piezoelectric vibrator is appropriately used as it is excellent from the point of view of reduction in the thickness and the like.

Here, Patent Citation 1 discloses a configuration in which a recess is formed in the lid of a thin glass plate and a piezoelectric vibrating reed is mounted in the recess. In addition, this recess is formed by etching the surface of the thin glass plate or by an integral molding method such as embossing molding of a glass material.

[Patent Citation 1] JP-A-2002-353766

Incidentally, in the case of forming a cavity in a base substrate or a lid substrate by press molding as in Patent Citation 1, the cavity bottom surface becomes a rough surface and lots of fine pinholes are formed on the surface. Specifically, as shown in FIG. 24, a recess 203a is formed in a lid substrate 203 in a package 201 which includes a base substrate 202 and the lid substrate 203. That is, a cavity C is formed by bonding both the substrates 202 and 203 to each other such that the recess 203a faces the base substrate 202. Here, if the recess 203a is formed by press molding, fine irregularities are present on the surface 203b of the recess 203a, and a pinhole P1 where the depth abruptly increases is formed in some places. A state where the pinhole P1 is formed in this way becomes a cause of deficiency of the flexural strength of the package, and this may affect the reliability of the product. In addition, when adjusting the thickness of a substrate by performing polishing or the like on the substrate after cavity formation, an abrasive grain in polishing liquid enters the pinhole P1, and it may remain in the pinhole P1 even if the substrate is washed thereafter. Then, when heating both the substrates 202 and 203 at the time of subsequent anodic bonding or the like, gas is generated from the abrasive grain. As a result, the product characteristics in a product, in which the airtightness in a package is important, may be degraded.

### SUMMARY OF THE INVENTION

Therefore, the present invention has been made in view of the above-described situation, and it is an object of the present invention to provide a package manufacturing method capable of improving the flexural strength in a package in which a cavity is formed in a substrate by press molding, a piezoelectric vibrator manufacturing method, an oscillator, an electronic device, and a radio-controlled timepiece.

The present invention provides the following means in order to solve the problem.

A package manufacturing method related to the present invention is a method of manufacturing a package with a recessed cavity formed in at least one of first and second substrates formed of a glass material and is characterized in that it includes a cavity forming step of forming the cavity by performing press molding on at least one molded substrate of the first and second substrates and a heat treatment step of heating the molded substrate formed with the cavity.

In the package manufacturing method related to the present invention, a fine pinhole formed on the surface of the cavity at the time of press molding can be removed by performing heat treatment of the molded substrate after forming the cavity in the molded substrate by press molding. That is, since irregularities formed on the surface become smooth due to softening of the surface of the cavity, pinholes also disappear. Accordingly, since the strength of the molded substrate is improved, the flexural strength of the package can also be improved.

In addition, the package manufacturing method related to the present invention is characterized in that a polishing step of polishing a surface formed with the cavity is performed after the heat treatment step.

In the package manufacturing method related to the present invention, since polishing is performed after performing the heat treatment step, it is possible to prevent an abrasive grain used in the polishing step from entering a pinhole formed on the surface of the cavity. Therefore, since it is possible to prevent an abrasive grain from remaining on the cavity surface when the polishing step is completed, generation of gas in the cavity in the subsequent step can be prevented. That is, since the airtightness in the package can be ensured, degradation in the product characteristics can be prevented.

In addition, the package manufacturing method related to the present invention is characterized in that the molded substrate is formed of soda glass and the temperature in the heat treatment step is equal to or larger than 600° C. and equal to or smaller than 700° C.

In the package manufacturing method related to the present invention, a pinhole formed on the cavity surface can be removed by setting the temperature in the heat treatment step to an appropriate value when using a substrate formed of soda glass. Accordingly, since the strength of the molded substrate is improved, the flexural strength of the package can also be improved.

In addition, the package manufacturing method related to the present invention is characterized in that the temperature in the heat treatment step is equal to or larger than 670° C. and equal to or smaller than 680° C.

In the package manufacturing method related to the present invention, a pinhole formed on the cavity surface can be more reliably removed by setting the temperature in the heat treatment step to an appropriate value in a narrower range when using a substrate formed of soda glass. Accordingly, since the strength of the molded substrate is reliably improved, the flexural strength of the package can also be improved.

In addition, a method of manufacturing a piezoelectric vibrator related to the present invention is characterized in that it includes: a through hole forming step of forming a through hole, which communicates into the cavity, in the package manufactured by any of the manufacturing methods described above; a penetration electrode forming step of forming a penetration electrode by disposing a conductive material in the through hole; and a piezoelectric vibrating reed mounting step of disposing a piezoelectric vibrating reed in the cavity and electrically connecting the piezoelectric vibrating reed and the penetration electrode to each other.

In the piezoelectric vibrator manufacturing method related to the present invention, the piezoelectric vibrator is manufactured by forming a penetration electrode and a piezoelectric vibrating reed in a package in which a pinhole formed on the cavity surface has disappeared and the strength of the substrate has been improved. Accordingly, it is possible to provide a high-quality piezoelectric vibrator in which the flexural strength is ensured and which has an improved yield.

In addition, an oscillator related to the present invention is characterized in that the piezoelectric vibrator manufactured by the manufacturing method described above is electrically connected to an integrated circuit as a vibrator.

In addition, an electronic device related to the present invention is characterized in that the piezoelectric vibrator manufactured by the manufacturing method described above is electrically connected to a timepiece section.

In addition, a radio-controlled timepiece related to the present invention is characterized in that the piezoelectric vibrator manufactured by the manufacturing method described above is electrically connected to a filter section.

Since the oscillator, the electronic device, and the radio-controlled timepiece related to the present invention include the high-quality piezoelectric vibrator in which the flexural strength is ensured and which has an improved yield, they have high quality as the reliability of the operation is similarly improved.

According to the package manufacturing method related to the present invention, a fine pinhole formed on the surface of the cavity at the time of press molding can be removed by performing heat treatment of the molded substrate after forming the cavity in the molded substrate by press molding. That is, since irregularities formed on the surface become smooth due to softening of the surface of the cavity, pinholes also disappear. Accordingly, since the strength of the molded substrate is improved, the flexural strength of the package can also be improved.

### BRIEF DESCRIPTION OF DRAWINGS

FIG. 1 is an appearance perspective view showing an embodiment of a piezoelectric vibrator related to the present invention.

FIG. 2 is a view showing the internal configuration of the piezoelectric vibrator shown in FIG. 1 when a piezoelectric vibrating reed is viewed from above with a lid substrate removed.

FIG. 3 is a sectional view of the piezoelectric vibrator in the embodiment of the present invention (sectional view taken along the line A-A shown in FIG. 2).

FIG. 4 is an exploded perspective view of the piezoelectric vibrator shown in FIG. 1.

FIG. 5 is a top view of a piezoelectric vibrating reed which forms the piezoelectric vibrator shown in FIG. 1.

FIG. 6 is a bottom view of the piezoelectric vibrating reed shown in FIG. 5.

FIG. 7 is a sectional view taken along the line B-B of FIG. 5.

FIG. 8 is a flow chart showing the flow when manufacturing the piezoelectric vibrator shown in FIG. 1.

FIG. 9 is a view showing one step when manufacturing a piezoelectric vibrator according to the flow chart shown in FIG. 8, and is a view showing a state where a plurality of recesses is formed in a wafer for a lid substrate which becomes the origin of a lid substrate.

FIG. 10 is a view showing one step when manufacturing a piezoelectric vibrator according to the flow chart shown in FIG. 8, and is a sectional view showing the surface shape of a recess when the recess is formed in a wafer for a lid substrate by pressing.

FIG. 11 is a view showing one step when manufacturing a piezoelectric vibrator according to the flow chart shown in FIG. 8, and is a sectional view showing the surface shape of a recess after performing a heat treatment step on a wafer for a lid substrate.

FIG. 12 is a view showing one step when manufacturing a piezoelectric vibrator according to the flow chart shown in FIG. 8, and is a plan view showing the surface shape of a recess before the heat treatment step.

FIG. 13 is a view showing one step when manufacturing a piezoelectric vibrator according to the flow chart shown in FIG. 8, and is a plan view showing the surface shape of a recess after the heat treatment step.

FIG. 14 is a view showing one step when manufacturing a piezoelectric vibrator according to the flow chart shown in FIG. 8, and is a plan view showing the surface shape of a recess after the heat treatment step when the temperature in the heat treatment step is set to 680° C.

FIG. 15 is a view showing one step when manufacturing a piezoelectric vibrator according to the flow chart shown in FIG. 8, and is a plan view showing the surface shape of a recess after the heat treatment step when the temperature in the heat treatment step is set to 650° C.

FIG. 16 is a view showing one step when manufacturing a piezoelectric vibrator according to the flow chart shown in FIG. 8, and is a perspective view showing a change in the height of a recess before and after the heat treatment step when the temperature in the heat treatment step is set to 700° C.

FIG. 17 is a view showing one step when manufacturing a piezoelectric vibrator according to the flow chart shown in FIG. 8, and is a plan view showing the surface shape of a recess after the heat treatment step when the temperature in the heat treatment step is set to 600° C.

FIG. 18 is a view showing one step when manufacturing a piezoelectric vibrator according to the flow chart shown in FIG. 8, and is a view showing a state where a bonding film and a lead-out electrode are patterned on the top surface of a wafer for a base substrate.

FIG. 19 is a partially enlarged perspective view of the wafer for a base substrate in the state shown in FIG. 18.

FIG. 20 is a view showing one step when manufacturing a piezoelectric vibrator according to the flow chart shown in FIG. 8, and is an exploded perspective view of the wafer body in which a wafer for a base substrate and a wafer for a lid substrate are anodically bonded to each other in a state where a piezoelectric vibrating reed is housed in a cavity.

FIG. 21 is a configuration view showing an embodiment of an oscillator related to the present invention.

FIG. 22 is a configuration view showing an embodiment of an electronic device related to the present invention.

FIG. 23 is a configuration view showing an embodiment of a radio-controlled timepiece related to the present invention.

FIG. 24 is a sectional view of a conventional package, and is a view illustrating the surface shape of a recess when a recess is formed in a lid substrate by press molding.

### DETAILED DESCRIPTION OF THE PREFERRED EMBODIMENTS

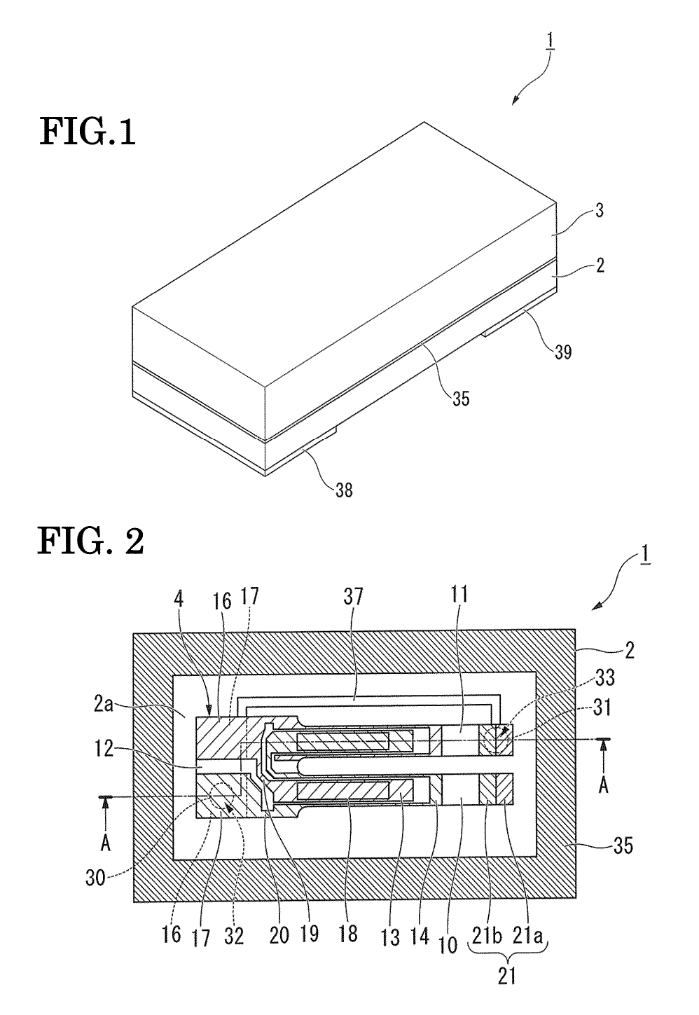

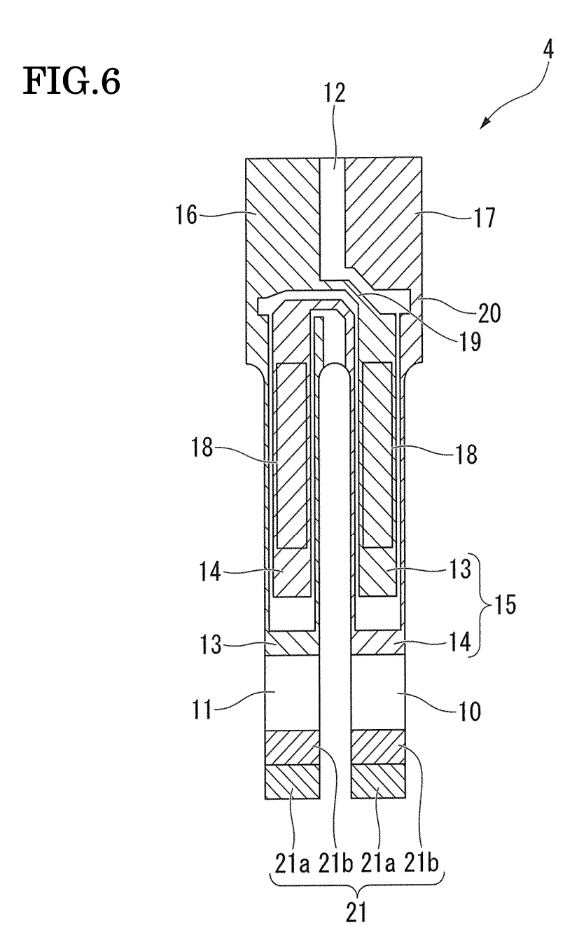

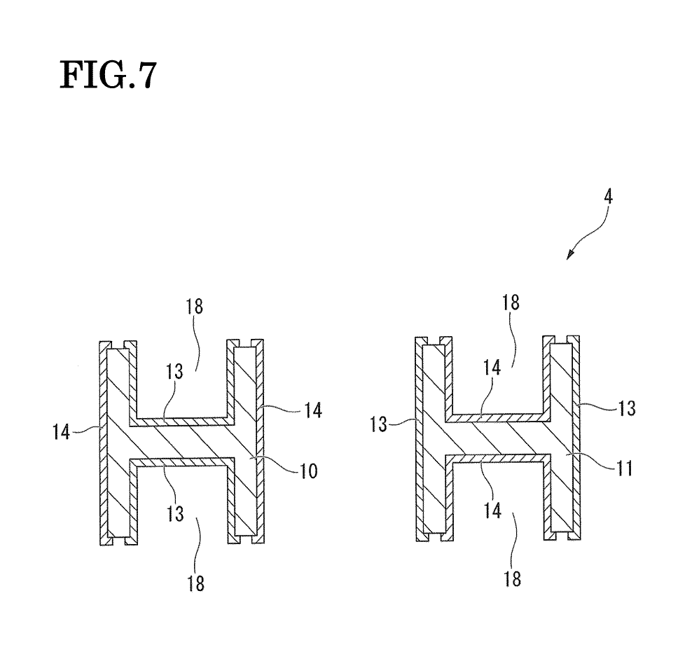

Next, embodiments related to the present invention will be described with reference to FIGS. 1 to 23.

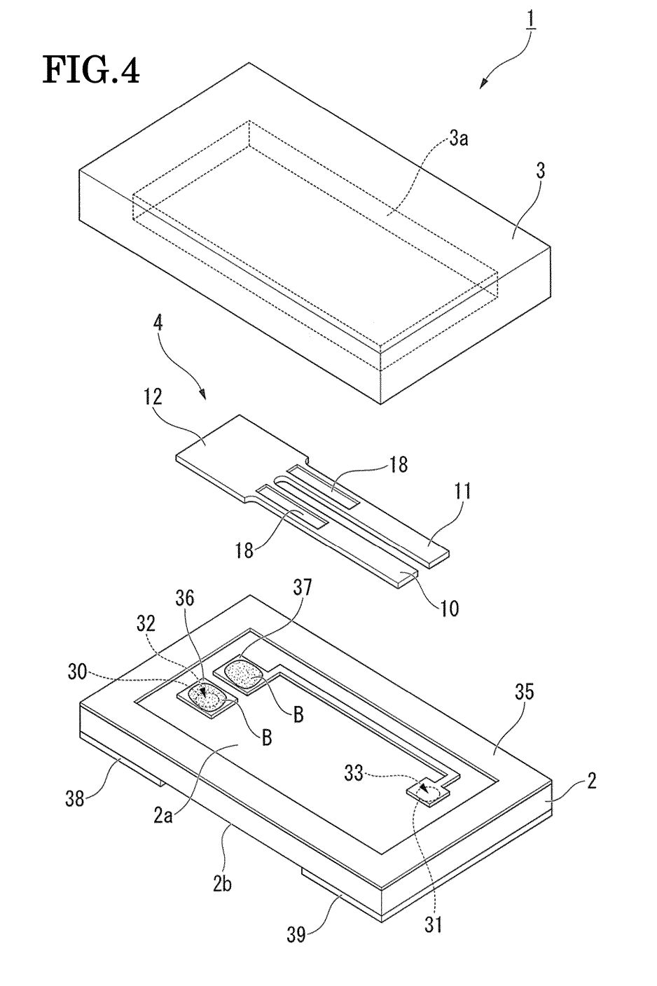

As shown in FIGS. 1 to 4, a piezoelectric vibrator 1 of the present embodiment is formed in a box shape in which two layers of a base substrate 2 and a lid substrate 3 are laminated, and is a surface mount type piezoelectric vibrator in which a piezoelectric vibrating reed 4 is housed in an internal cavity C. Moreover, for easy understanding of the drawings, an excitation electrode 15, lead-out electrodes 19 and 20, mount electrodes 16 and 17, and a weight metal film 21 of the piezoelectric vibrating reed 4, which will be described later, are not shown in FIG. 4.

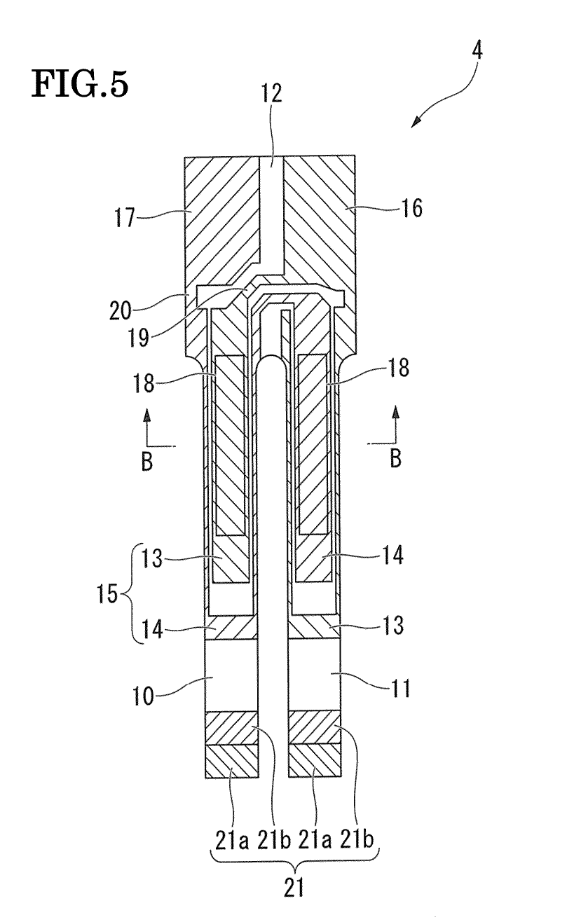

As shown in FIGS. 5 to 7, the piezoelectric vibrating reed 4 is a tuning fork type vibrating reed formed of a piezoelectric material, such as crystal, lithium tantalate, or lithium niobate, and vibrates when a predetermined voltage is applied.

This piezoelectric vibrating reed 4 has: a pair of vibrating arms 10 and 11 disposed in parallel; a base portion 12 which integrally fixes the base end sides of the pair of vibrating arms 10 and 11; an excitation electrode 15 formed by first and second excitation electrodes 13 and 14 which are formed on the outer surfaces of the pair of vibrating arms 10 and 11 in order to vibrate the pair of vibrating arms 10 and 11; and mount electrodes 16 and 17 electrically connected to the first and second excitation electrodes 13 and 14.

In addition, the piezoelectric vibrating reed 4 of the present embodiment includes a groove 18 which is formed on each of both principal surfaces of the pair of vibrating arms 10 and 11 along the longitudinal directions of the vibrating arms 10 and 11. This groove 18 is formed from the base end sides of the vibrating arms 10 and 11 to the approximate middle.

The excitation electrode 15 formed by the first and second excitation electrodes 13 and 14 is an electrode which vibrates the pair of vibrating arms 10 and 11 at a predetermined resonance frequency in a direction moving closer to or away from each other, and is formed on the outer surfaces of the pair of vibrating arms 10 and 11 by patterning in an electrically isolated state. Specifically, the first excitation electrode 13 is mainly formed on the groove 18 of one vibrating arm 10 and on both side surfaces of the other vibrating arm 11, and the second excitation electrode 14 is mainly formed on both side surfaces of one vibrating arm 10 and on the groove 18 of the other vibrating arm 11.

In addition, the first and second excitation electrodes 13 and 14 are electrically connected to the mount electrodes 16 and 17 through the lead-out electrodes 19 and 20 on both the principal surfaces of the base portion 12, respectively. In addition, a voltage is applied to the piezoelectric vibrating reed 4 through the mount electrodes 16 and 17.

In addition, the excitation electrode 15, the mount electrodes 16 and 17, and the lead-out electrodes 19 and 20 described above are formed of conductive films, such as chromium (Cr), nickel (Ni), aluminum (Al), and titanium (Ti), for example.

In addition, the weight metal film 21 for adjusting (frequency adjustment) the vibrating states of the pair of vibrating arms 10 and 11 to vibrate within a predetermined frequency range is formed at the distal ends of the vibrating arms 10 and 11. In addition, this weight metal film 21 is divided into a rough adjustment film 21a, which is used when performing rough adjustment of a frequency, and a fine adjustment film 21b, which is used when performing fine adjustment of a frequency. By performing frequency adjustment using the rough adjustment film 21a and the fine adjustment film 21b, the frequency of the pair of the vibrating arms 10 and 11 can be set to fall within the nominal frequency range of the device.

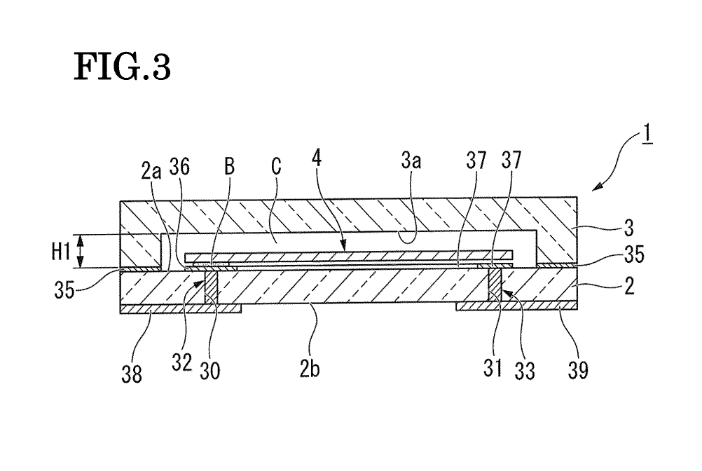

As shown in FIGS. 3 and 4, the piezoelectric vibrating reed 4 configured in this way is bump-bonded to the top surface 2a of the base substrate 2 using a bump B made of gold or the like. More specifically, the piezoelectric vibrating reed 4 is bump-bonded in a state where the pair of mount electrodes 16 and 17 is in contact with two bumps B formed on lead-out electrodes 36 and 37, which are patterned on the top surface 2a of the base substrate 2 and will be described later. As a result, the piezoelectric vibrating reed 4 is supported in a state floated from the top surface 2a of the base substrate 2, and the mount electrodes 16 and 17 and the lead-out electrodes 36 and 37 are electrically connected to each other, respectively.

The above-described lid substrate 3 is a transparent insulating substrate made of a glass material, for example, soda glass, and is formed in an approximate plate shape as shown in FIGS. 1, 3, and 4. In addition, a rectangular recess 3a in which the piezoelectric vibrating reed 4 is housed is formed at the bonding surface side to which the base substrate 2 is bonded.

This recess 3a is a recess for a cavity that becomes a cavity C, in which the piezoelectric vibrating reed 4 is housed, when both the substrates 2, 3 are stacked up. In addition, the lid substrate 3 is anodically bonded to the base substrate 2 in a state where the recess 3a faces the base substrate 2.

Similar to the lid substrate 3, the base substrate 2 described above is a transparent insulating substrate made of a glass material, for example, soda glass. As shown in FIGS. 1 to 4, the base substrate 2 is formed in an approximate plate shape with a size in which it can be stacked up on the lid substrate 3.

A pair of through holes 30 and 31 passing through the base substrate 2 is formed in this base substrate 2. In this case, the pair of through holes 30 and 31 is formed so as to be settled in the cavity C. When the through holes 30 and 31 of the present embodiment are explained in more detail, one through hole 30 is formed at the position corresponding to the base portion 12 side of the mounted piezoelectric vibrating reed 4, and the other through hole 31 is formed at the position corresponding to the distal end sides of the vibrating arms 10 and 11. Moreover, in the present embodiment, the through holes 30 and 31 passing through the base substrate 2 straightly from the bottom surface 2b of the base substrate 2 toward the top surface 2a are formed. In addition, the shapes of the through holes 30 and 31 are not limited to this case, and they may be through holes with a tapered sectional shape the diameter of which gradually decreases. In any case, it is necessary that a through hole passes through the base substrate 2.

In addition, a pair of penetration electrodes 32 and 33 formed so as to be embedded in the through holes 30 and 31 is formed in the pair of through holes 30 and 31, respectively. As shown in FIG. 3, these penetration electrodes 32 and 33 are formed by a conductive material such as silver paste integrally fixed to the through holes 30 and 31 by baking. The penetration electrodes 32 and 33 serve to maintain the airtightness in the cavity C by completely blocking the through holes 30 and 31 and also to make external electrodes 38 and 39 electrically connected to the lead-out electrodes 36 and 37 which will be described later, respectively.

On the top surface 2a side (bonding surface side to which the lid substrate 3 is bonded) of the base substrate 2, a bonding film 35 for anodic bonding and the pair of lead-out electrodes 36 and 37 are patterned by a conductive material, for example, aluminum, as shown in FIGS. 1 to 4. Among them, the bonding film 35 is formed along the edge of the base substrate 2 so as to surround the periphery of the recess 3a formed in the lid substrate 3.

In addition, the pair of lead-out electrodes 36 and 37 is patterned to electrically connect one penetration electrode 32 of the pair of penetration electrodes 32 and 33 to one mount electrode 16 of the piezoelectric vibrating reed 4 and electrically connect the other penetration electrode 33 to the other mount electrode 17 of the piezoelectric vibrating reed 4.

More specifically, one lead-out electrode 36 is formed immediately above one penetration electrode 32 so as to be located immediately below the base portion 12 of the piezoelectric vibrating reed 4. In addition, the other lead-out electrode 37 is formed so as to be lead from the position adjacent to one lead-out electrode 36 to the distal end side of the vibrating arms 10 and 11 along the vibrating arms 10 and 11 and be then located immediately above the other penetration electrode 33.

In addition, the bump B is formed on each of the pair of lead-out electrodes 36 and 37, and the piezoelectric vibrating reed 4 is mounted using the bump B. As a result, one mount electrode 16 of the piezoelectric vibrating reed 4 is electrically connected to one penetration electrode 32 through one lead-out electrode 36, and the other mount electrode 17 is electrically connected to the other penetration electrode 33 through the other lead-out electrode 37.

In addition, the external electrodes 38 and 39 electrically connected to the pair of penetration electrodes 32 and 33, respectively, are formed on the bottom surface 2b of the base substrate 2, as shown in FIGS. 1, 3, and 4. That is, one external electrode 38 is electrically connected to the first excitation electrode 13 of the piezoelectric vibrating reed 4 through one penetration electrode 32 and one lead-out electrode 36. In addition, the other external electrode 39 is electrically connected to the second excitation electrode 14 of the piezoelectric vibrating reed 4 through the other penetration electrode 33 and the other lead-out electrode 37.

When operating the piezoelectric vibrator 1 configured in this way, a predetermined driving voltage is applied to the external electrodes 38 and 39 formed on the base substrate 2. Accordingly, since a current can be made to flow to the excitation electrode 15 of the piezoelectric vibrating reed 4 which is formed by the first and second excitation electrodes 13 and 14, the pair of vibrating arms 10 and 11 can vibrate at a predetermined frequency in a direction moving closer to or away from each other. In addition, using the vibration of the pair of vibrating arms 10 and 11, it can be used as a time source, a timing source of a control signal, a reference signal source, and the like.

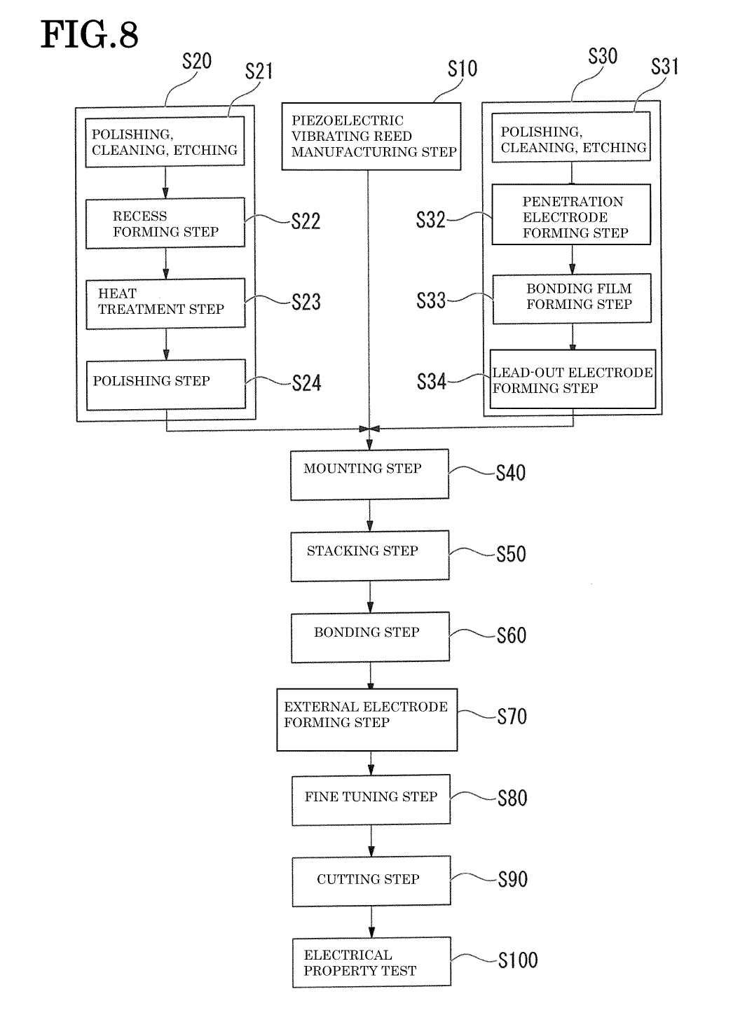

Next, a manufacturing method of manufacturing a plurality of piezoelectric vibrators 1 described above simultaneously using a wafer 40 for a base substrate and a wafer 50 for a lid substrate will be described below referring to the flow chart shown in FIG. 8.

First, a piezoelectric vibrating reed manufacturing step is performed to manufacture the piezoelectric vibrating reed 4 shown in FIGS. 5 to 7 (S10). Specifically, first, a Lambert ore made of crystal is sliced at a predetermined angle to form a wafer with a fixed thickness. Then, this wafer is rubbed for rough processing, and the affected layer is removed by etching. Then, the wafer is subjected to mirror polishing processing, such as polishing, to make the wafer have a predetermined thickness. Then, after performing appropriate processing, such as washing, on the wafer, the wafer is patterned to have the outer shape of the piezoelectric vibrating reed 4 by a photolithographic technique and a metal film is formed and patterned. As a result, the excitation electrode 15, the lead-out electrodes 19 and 20, the mount electrodes 16 and 17, and the weight metal film 21 are formed. In this way, a plurality of piezoelectric vibrating reeds 4 can be manufactured.

In addition, after manufacturing the piezoelectric vibrating reed 4, rough adjustment of a resonance frequency is performed. This is performed by changing the weight by emitting a laser beam onto the rough adjustment film 21a of the weight metal film 21 to evaporate a part of the rough adjustment film 21a. In addition, fine adjustment for adjusting the resonance frequency more accurately is performed after mounting. This will be described later.

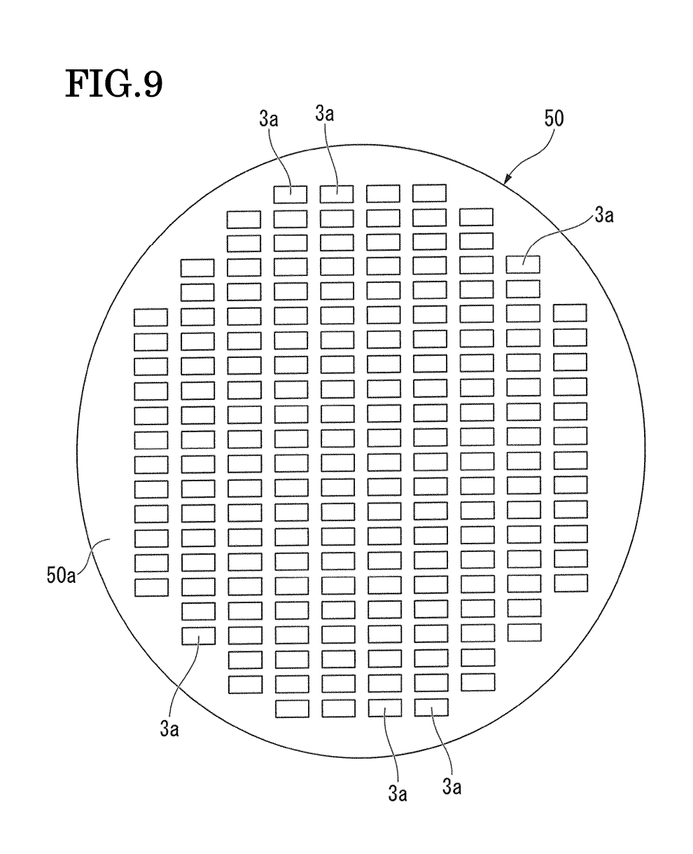

Then, a first wafer manufacturing step of manufacturing the wafer 50 for a lid substrate, which becomes the lid substrates 3 later, is performed until a state immediately before performing anodic bonding (S20). First, the wafer 50 for a lid substrate formed of soda glass is polished up to a predetermined thickness and washed, and then the disk-shaped the wafer 50 for a lid substrate, from which an affected layer located at the outermost surface has been removed by etching or the like, is formed as shown in FIG. 9 (S21). Then, a recess forming step of forming the plurality of recesses 3a for a cavity in a matrix by pressing is performed on the bonding surface of the wafer for a lid substrate 50 (S22). Specifically, a die formed with a protruding portion corresponding to the recess 3a is disposed to be in contact with a surface 50a of the wafer 50 for a lid substrate and is put into a heating furnace in this state. Then, by heating it at about 1000° C., the wafer 50 for a lid substrate becomes soft and the die sinks into the surface 50a of the wafer 50 for a lid substrate. Then, the wafer 50 for a lid substrate is taken out from the heating furnace and is cooled to form the recess 3a in the wafer 50 for a lid substrate. In addition, the die is detached from the wafer 50 for a lid substrate after cooling.

Then, the wafer 50 for a lid substrate in which the recess 3a is formed is put into an electric furnace to perform a heat treatment step (S23). In this heat treatment step, the inside of the furnace is heated at 670° C. to 680° C., for example, and the wafer 50 for a lid substrate is placed in the furnace for about 30 minutes, for example. By performing heat treatment of the wafer 50 for a lid substrate in this way, a pinhole formed on the surface of the recess 3a can be removed.

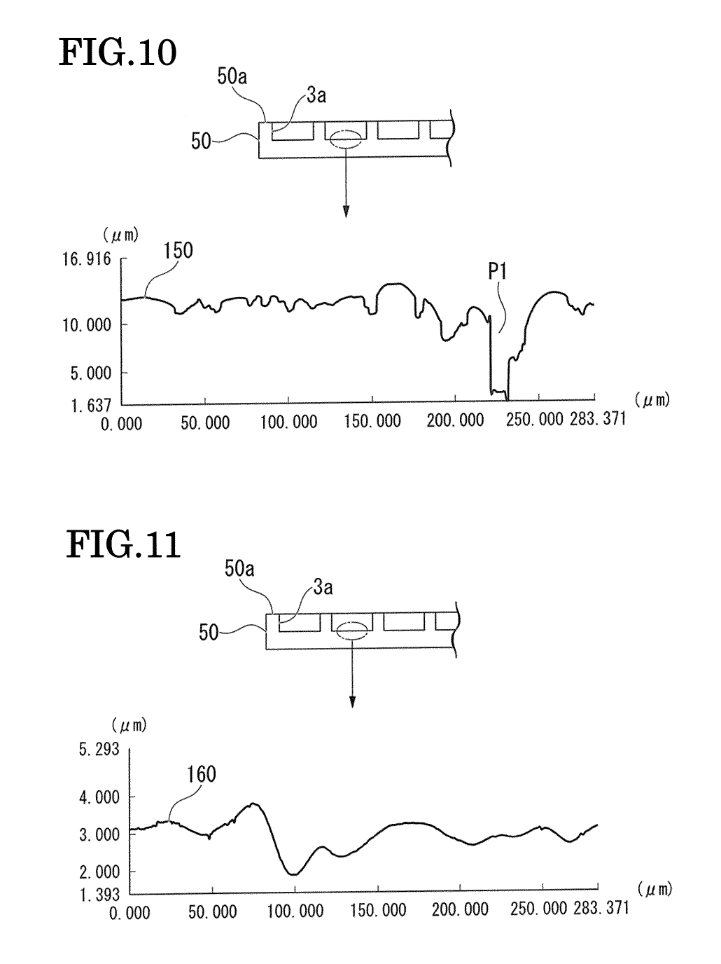

Specifically, as shown in FIGS. 10 and 11, the sectional shape 160 (refer to FIG. 11) of the recess 3a after the heat treatment step becomes a smooth sectional shape due to the heat treatment, compared with the sectional shape 150 (refer to FIG. 10) of the recess 3a before the heat treatment step. In addition, it can be seen that the pinhole P1 is removed by performing the heat treatment, although a pinhole P1 with a step difference of about 10 μm is formed in the sectional shape 150. In addition, it can be seen that in the sectional shape 160 after the heat treatment step, a difference in height is small since a difference in the height of the sectional surface is about 2 μm. Moreover, in the present embodiment, the thickness of a region where the recess 3a in the wafer 50 for a lid substrate is formed is about 150 μm. Accordingly, the pinhole P1 is formed up to the depth of about 7% of the total thickness, resulting in a reduction in the flexural strength of the lid substrate 3. However, since the pinhole P1 is removed by performing the heat treatment step, a desired flexural strength is ensured.

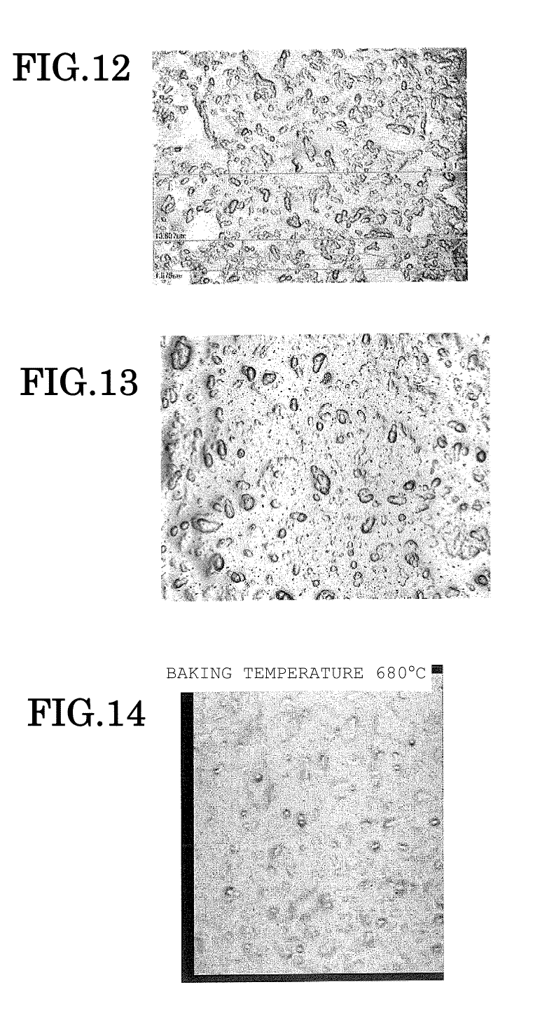

In addition, as shown in FIGS. 12 and 13, it can be seen that the surface shape 13 (refer to FIG. 13) of the recess 3a after the heat treatment step becomes smooth compared with the surface shape (refer to FIG. 12) of the recess 3a before the heat treatment step and the number of dents is decreased accordingly. That is, it can be seen that the surface becomes smooth by performing heat treatment.

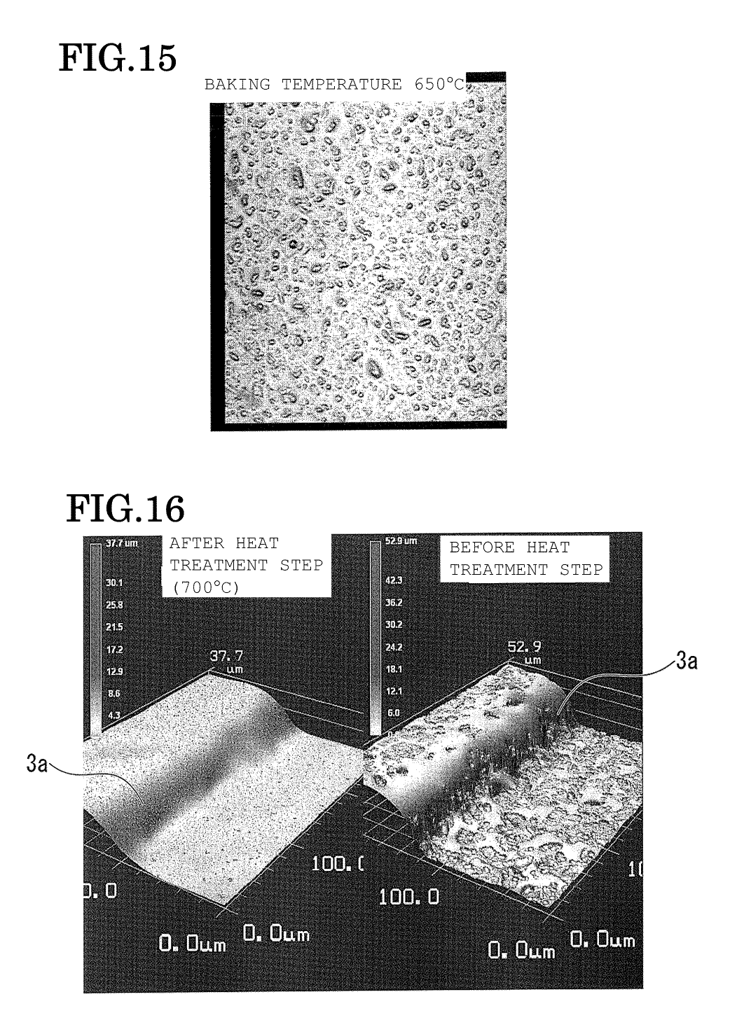

In addition, as shown in FIGS. 14 and 15, it can be seen that the pinhole P1 can be more reliably removed and the surface becomes smoother by setting the inside temperature of the electric furnace in the heat treatment step to 680° C. (refer to FIG. 14), compared with the case where heat treatment is performed with the inside temperature of the electric furnace as 650° C. (refer to FIG. 15).

Moreover, as shown in FIG. 16, it can be seen that the surface of the recess 3a becomes smoother if the inside temperature of the electric furnace in the heat treatment step is set to 700° C. In this case, however, since softening of the wafer 50 for a lid substrate accelerates further, the height H1 (refer to FIG. 3) of the recess 3a is decreased. In FIG. 16, the height H1 of the recess 3a before heat treatment is 52.9 μm, while the height H1 after heat treatment is 37.7 μm. Accordingly, the height H1 of the recess 3a is decreased. If the height H1 of the recess 3a becomes equal to or smaller than a predetermined value, a problem, such as contact between the piezoelectric vibrating reed 4 and the recess 3a, may occur when mounting the piezoelectric vibrating reed 4 thereafter. Accordingly, the maximum temperature in the heat treatment step is 700° C.

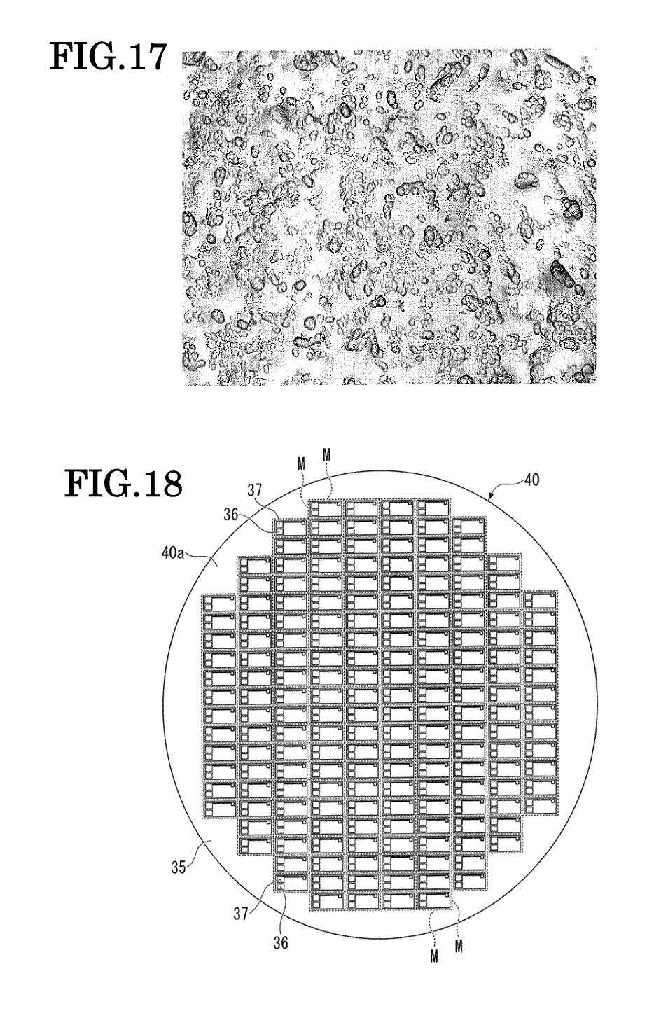

On the other hand, the minimum temperature in the heat treatment step is 600° C. Even if the wafer 50 for a lid substrate is put into the electric furnace for heat treatment, the surface shape of the recess 3a is not changed if the temperature is too low. In the case of using soda glass as the wafer 50 for a lid substrate as in the present embodiment, it was confirmed that the pinhole P1 of the recess 3a was removed if the temperature of the electric furnace was set to 600° C. In addition, FIG. 17 shows the surface shape of the recess 3a when the temperature in the heat treatment step is set to 600° C.

After the heat treatment step ends, the surface formed with the recess 3a is polished (S24) in preparation for a subsequent bonding step (S60). In addition, in this polishing process, an abrasive grain used for polishing does not enter the pinhole P1 because the pinhole P1 is removed in the previous heat treatment step. The first wafer manufacturing step ends when the polishing of the surface of the recess 3a is completed.

Then, at the same time as the above step or at a timing before or after the above step, a second wafer manufacturing step of manufacturing the wafer 40 for a base substrate, which becomes the base substrates 2 later, is performed until a state immediately before performing anodic bonding (S30). First, soda glass is polished up to a predetermined thickness and washed and then the disk-shaped wafer 40 for a base substrate, from which an affected layer located at the outermost surface has been removed by etching or the like, is formed (S31). Then, a penetration electrode forming step of forming a plurality of pairs of penetration electrodes 32 and 33 in the wafer 40 for a base substrate is performed (S32). The penetration electrodes 32 and 33 are formed by forming the through holes 30 and 31 at the predetermined positions of the wafer 40 for a base substrate, filling the through holes 30 and 31 with, for example, silver paste and then fixing the paste material by baking, and finally polishing the surface of the wafer 40 for a base substrate.

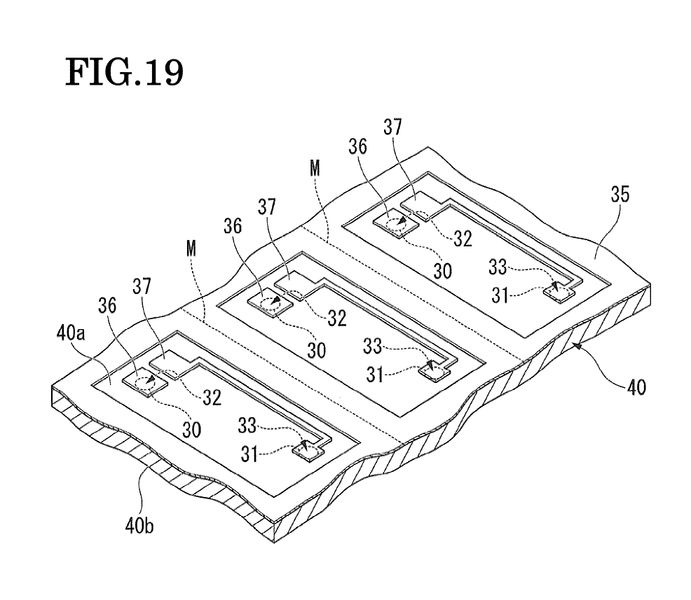

Then, by patterning a conductive material on the top surface 40a of the wafer 40 for a base substrate, a bonding film forming step of forming the bonding film 35 is performed (S33) and at the same time, a lead-out electrode forming step of forming the plurality of lead-out electrodes 36 and 37 electrically connected to the pair of penetration electrodes 32 and 33, respectively, is performed (S34), as shown in FIGS. 18 and 19. In addition, the dotted line M shown in FIGS. 18 and 19 indicates a cutting line which is cut in a cutting step performed later.

In particular, the penetration electrodes 32 and 33 become approximately even with the top surface 40a of the wafer 40 for a base substrate, as described above. Accordingly, the lead-out electrodes 36 and 37 patterned on the top surface 40a of the wafer 40 for a base substrate are in close contact with the penetration electrodes 32 and 33 without generating a gap or the like therebetween. As a result, an electrical connection between one lead-out electrode 36 and one penetration electrode 32 and an electrical connection between the other lead-out electrode 37 and the other penetration electrode 33 can be ensured. At this point in time, the second wafer manufacturing step ends.

Incidentally, although the process order in FIG. 8 is set such that the lead-out electrode forming step (S34) is performed after the bonding film forming step (S33), the bonding film forming step (S33) may be performed after the lead-out electrode forming step (S34) contrary to the process order, or both steps may be performed simultaneously. Even if any process order is adopted, the same operations and effects can be obtained. Thus, the process order may be appropriately changed when necessary.

Then, a mounting step of bonding the plurality of manufactured piezoelectric vibrating reeds 4 to the top surface 40a of the wafer 40 for a base substrate through the lead-out electrodes 36 and 37 is performed (S40). First, the bump B made of gold or the like is formed on each of the pair of lead-out electrodes 36 and 37. Then, the base portion 12 of the piezoelectric vibrating reed 4 is placed on the bump B and then the piezoelectric vibrating reed 4 is pressed against the bump B while heating the bump B at a predetermined temperature. As a result, the piezoelectric vibrating reed 4 is mechanically supported by the bump B and is also electrically connected to the mount electrodes 16 and 17 and the lead-out electrodes 36 and 37. Accordingly, at this point in time, the pair of excitation electrodes 15 of the piezoelectric vibrating reed 4 is electrically connected to the pair of penetration electrodes 32 and 33, respectively.

In particular, since the piezoelectric vibrating reed 4 is bump-bonded, the piezoelectric vibrating reed 4 is supported in a state floated from the top surface 40a of the wafer 40 for a base substrate.

After the mounting of the piezoelectric vibrating reed 4 ends, a stacking step of stacking the wafer 50 for a lid substrate wafer 50 on the wafer 40 for a base substrate is performed (S50). Specifically, both the wafers 40 and 50 are aligned at the correct positions using reference marks (not shown) or the like as an index. As a result, the mounted piezoelectric vibrating reed 4 is housed in the recess 3a formed in the wafer 40 for a base substrate and the cavity C surrounded by both the wafers 40 and 50.

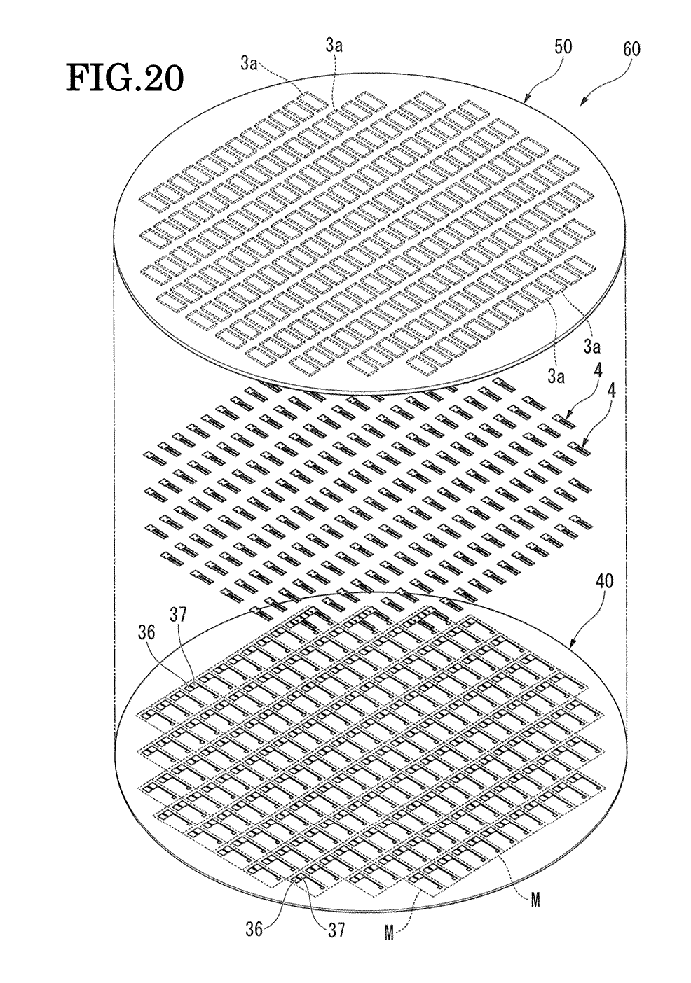

After the stacking step, the two stacked wafers 40 and 50 are put into an anodic bonding apparatus (not shown), in which a bonding step of performing anodic bonding of the two stacked wafers 40 and 50 by applying a predetermined voltage in the predetermined vacuum atmosphere and temperature atmosphere is performed (S60). Specifically, a predetermined voltage is applied between the bonding film 35 and the wafer 50 for a lid substrate. Then, an electrochemical reaction occurs on the interface between the bonding film 35 and the wafer 50 for a lid substrate, and both the bonding film 35 and the wafer 50 for a lid substrate come in close contact with each other to be anodically bonded. As a result, since the piezoelectric vibrating reed 4 can be sealed in the cavity C, it is possible to acquire a wafer body 60 shown in FIG. 20 in which the wafer 40 for a base substrate and the wafer 50 for a lid substrate are bonded to each other.

Here, in the present embodiment, since the pinhole P1 is not formed on the surface of the recess 3a of the wafer 50 for a lid substrate, an abrasive grain used in the polishing step does not enter and remain in the pinhole P1. Accordingly, even if the wafer body 60 is heated at the time of anodic bonding, gas is not generated in the cavity C. That is, anodic bonding can be performed while reliably maintaining the vacuum state in the cavity C. Moreover, in FIG. 20, in order to increase the viewability, a state where the wafer body 60 is disassembled is shown and illustration of the wafer 40 for a base substrate to the bonding film 35 is omitted. In addition, the dotted line M shown in FIG. 20 indicates a cutting line which is cut in a cutting step performed later.

Incidentally, when performing anodic bonding, the through holes 30 and 31 formed in the wafer 40 for a base substrate are completely blocked by the penetration electrodes 32 and 33. Accordingly, the airtightness in the cavity C is not influenced by the through holes 30 and 31.

Then, after the anodic bonding described above ends, an external electrode forming step of forming a plurality of pairs of external electrodes 38 and 39 electrically connected to the pair of penetration electrodes 32 and 33, respectively, by patterning a conductive material on the bottom surface 40b (refer to FIG. 19) of the wafer 40 for a base substrate is performed (S70). Through this step, the piezoelectric vibrating reed 4 which is sealed in the cavity C can be operated using the external electrodes 38 and 39.

In particular, also in the case of performing this step, the penetration electrodes 32 and 33 are approximately even with the bottom surface 40b of the wafer 40 for a base substrate, similar to the case when forming the lead-out electrodes 36 and 37. Accordingly, the patterned external electrodes 38 and 39 are in close contact with the penetration electrodes 32 and 33 without generating a gap or the like therebetween. As a result, electrical connections between the external electrodes 38 and 39 and the penetration electrodes 32 and 33 can be ensured.

Then, a fine adjustment step of setting the frequency of each piezoelectric vibrator 1, which is sealed in the cavity C, to fall within a predetermined range by fine adjustment in a state of the wafer body 60 is performed (S80). Specifically, a voltage is applied to the external electrodes 38 and 39, which are formed on the bottom surface 40b of the wafer 40 for a base substrate, in order to vibrate the piezoelectric vibrating reed 4. Then, a laser beam is emitted from the outside through the wafer 50 for a lid substrate while measuring the frequency, so that the fine adjustment film 21b of the weight metal film 21 is evaporated. As a result, since the weight of the pair of vibrating arms 10 and 11 at the distal end side thereof changes, the frequency of the piezoelectric vibrating reed 4 can be finely adjusted to fall within a predetermined range of a nominal frequency.

After the fine adjustment of a frequency ends, a cutting step of cutting the bonded wafer body 60 into pieces by cutting it along the cutting line M shown in FIG. 20 is performed (S90). As a result, it is possible to simultaneously manufacture the plurality of surface mount type piezoelectric vibrators 1 shown in FIG. 1, which has a two-layer structure and in which the piezoelectric vibrating reed 4 is sealed in the cavity C formed between the base substrate 2 and the lid substrate 3 that are anodically bonded to each other.

In addition, the fine adjustment step (S80) may be performed after performing the cutting step (S90) to cut the wafer body into small pieces of the individual piezoelectric vibrators 1. However, since the fine adjustment can be performed in a state of the wafer body 60 by performing the fine adjustment step (S80) first as described above, fine adjustment of the plurality of piezoelectric vibrators 1 can be more efficiently performed. Accordingly, this is preferable since throughput can be improved.

Then, testing of internal electrical properties is performed (S100). That is, resonance frequency, resonance resistance value, drive level characteristics (exciting power dependency of resonance frequency and resonance resistance value), and the like of the piezoelectric vibrating reed 4 are checked by measurement. In addition, an insulation resistance characteristic and the like are checked together. Finally, visual inspection of the piezoelectric vibrator 1 is performed to finally check the dimension, quality, and the like. Thus, manufacturing of the piezoelectric vibrator 1 ends.

According to the present embodiment, since heat treatment of the wafer 50 for a lid substrate is performed after forming the recess 3a (cavity C) by press molding in the wafer 50 for a lid substrate formed of a glass material, it is possible to remove the fine pinhole P1 formed on the surface of the recess 3a at the time of press molding. That is, since irregularities formed on the surface become smooth due to softening of the surface of the recess 3a, the pinhole P1 also disappears. Accordingly, since the strength of the lid substrate 3 formed from the wafer 50 for a lid substrate is improved, the flexural strength of the piezoelectric vibrator 1 is also improved.

In addition, since the polishing step of polishing the surface of the recess 3a is performed after the heat treatment step of the wafer 50 for a lid substrate, it is possible to prevent an abrasive grain used in the polishing step from entering the pinhole P1 formed on the surface of the recess 3a. Accordingly, since it is possible to prevent an abrasive grain from remaining on the surface of the recess 3a when the polishing step is completed, generation of gas in the cavity C in the subsequent step can be prevented. That is, since the airtightness in the piezoelectric vibrator 1 can be ensured, degradation in the product characteristics can be prevented.

In addition, the pinhole P1 formed on the surface of the recess 3 can be removed by setting the temperature in the heat treatment step to be equal to or larger than 600° C. and equal to or smaller than 700° C. using a wafer, which is formed of soda glass, as the wafer 50 for a lid substrate. Accordingly, since the strength of the lid substrate 3 is improved, the flexural strength of the piezoelectric vibrator 1 is also improved.

In addition, it is preferable that the temperature in the heat treatment step described above is set to be equal to or larger than 670° C. and equal to or smaller than 680° C. That is, the pinhole P1 formed on the surface of the recess 3a can be more reliably removed by setting the temperature in the heat treatment step to an appropriate value in a narrower range. Accordingly, since the strength of the lid substrate 3 is reliably improved, the flexural strength of the piezoelectric vibrator 1 is also reliably improved.

### (Oscillator)

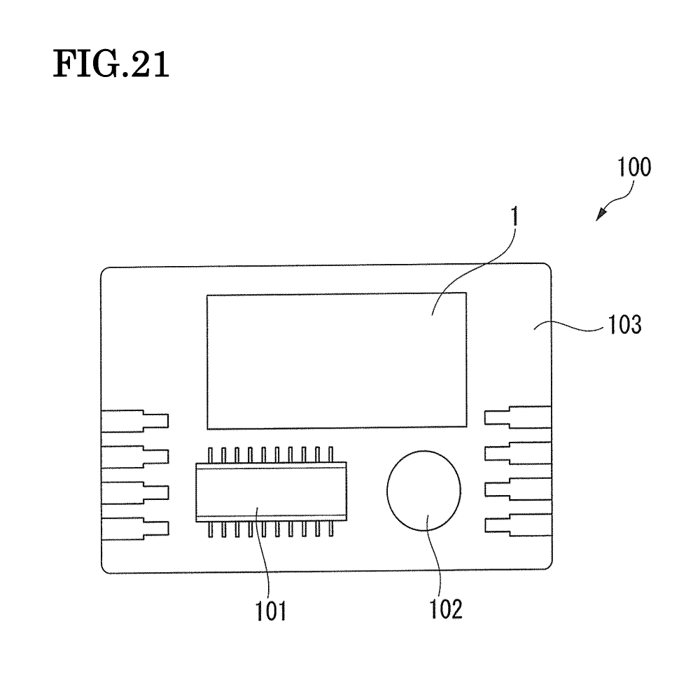

Next, an embodiment of an oscillator related to the present invention will be described referring to FIG. 21.

An oscillator 100 of the present embodiment includes the piezoelectric vibrator 1 configured as a vibrator electrically connected to an integrated circuit 101, as shown in FIG. 21. This oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured in this way, the piezoelectric vibrating reed 4 in the piezoelectric vibrator 1 vibrates when a voltage is applied to the piezoelectric vibrator 1. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as a vibrator.

In addition, by selectively setting the configuration of the integrated circuit 101, for example, an RTC (Real Time Clock) module, according to the demands, it is possible to add a function of controlling the operation date or time of the corresponding device or an external device or of providing the time or calendar in addition to a single functional oscillator for a timepiece.

As described above, since the oscillator 100 of the present embodiment includes the high-quality piezoelectric vibrator 1 in which the flexural strength is ensured and the airtightness in the cavity C is reliably ensured and which has an improved yield, the oscillator 100 itself can also similarly have high quality as its electrical conductivity is stably ensured and the reliability of the operation is improved. In addition to this, it is possible to obtain a highly precise frequency signal which is stable over a long period of time.

### (Electronic Device)

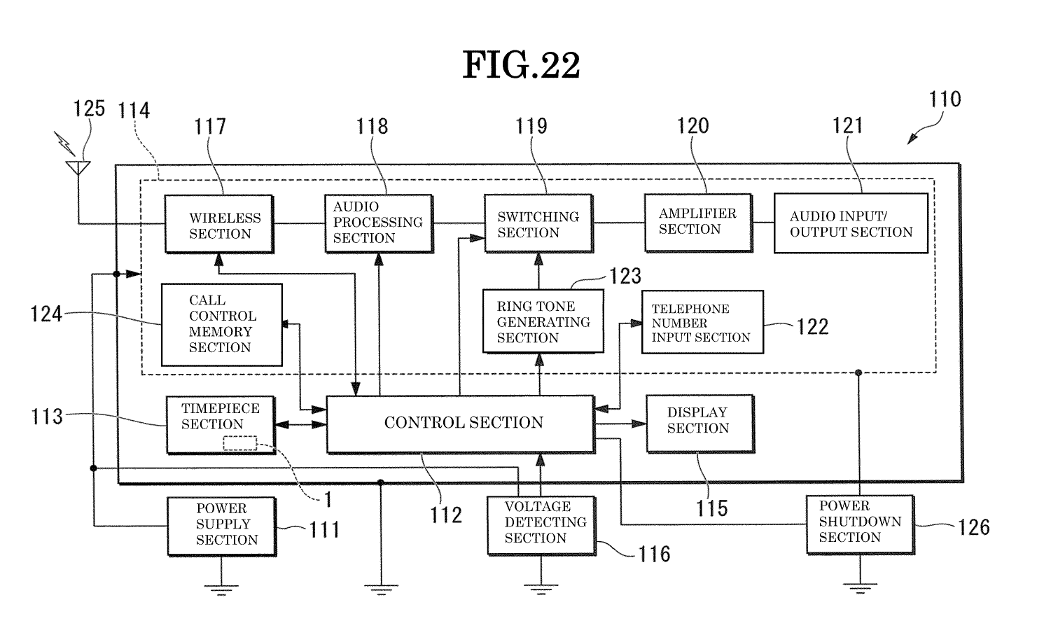

Next, an embodiment of an electronic device related to the present invention will be described with reference to FIG. 22. In addition, a portable information device 110 including the above piezoelectric vibrator 1 will be described as an example of the electronic device.

First, the portable information device 110 of the present embodiment is represented by a mobile phone, for example, and has been developed and improved from a wristwatch in the related art. The portable information device 110 is similar to a wristwatch in its external appearance, and a liquid crystal display is disposed in a portion equivalent to a dial pad so that the current time and the like can be displayed on the screen. In addition, when this is used as a communication apparatus, it is possible to remove it from the wrist and to perform the same communication as a mobile phone in the related art through a speaker and a microphone built in an inner portion of the band. Nevertheless, the portable information device 110 is very small and light compared with a mobile phone in the related art.

Next, the configuration of the portable information device 110 of the present embodiment will be described. As shown in FIG. 22, the portable information device 110 includes the piezoelectric vibrator 1 and a power supply section 111 for supplying power. The power supply section 111 is formed of a lithium secondary battery, for example. A control section 112 which performs various kinds of control, a timepiece section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display the current time. In addition, the control section 112 includes a ROM in which a program is written in advance, a CPU which reads and executes a program written in the ROM, a RAM used as a work area of the CPU, and the like.

The timepiece section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted into an electrical signal due to the piezoelectric property of crystal and is then input to the oscillation circuit as an electrical signal. The output of the oscillation circuit is binarized to be counted by the register circuit and the counter circuit. Then, a signal is transmitted to or received from the control section 112 through the interface circuit, and the current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to the predetermined level. The audio input/output section 121 is formed by a speaker, a microphone, and the like, and amplifies a ring tone or incoming sound or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. In addition, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set in advance as the lowest voltage necessary to operate the communication section 114 stably. For example, it is about 3 V. The control section 112 which has received the notification of a voltage drop from the voltage detecting section 116 disables the operations of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detection section 116 and the control section 112. This message may be a character message, or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 of the present embodiment includes the high-quality piezoelectric vibrator 1 in which the flexural strength is ensured and the airtightness in the cavity C is reliably ensured and which has an improved yield, the portable information device itself can also similarly have high quality as its electrical conductivity is stably ensured and the reliability of the operation is improved. In addition to this, it is possible to display highly precise timepiece information which is stable over a long period of time.

### (Radio-Controlled Timepiece)

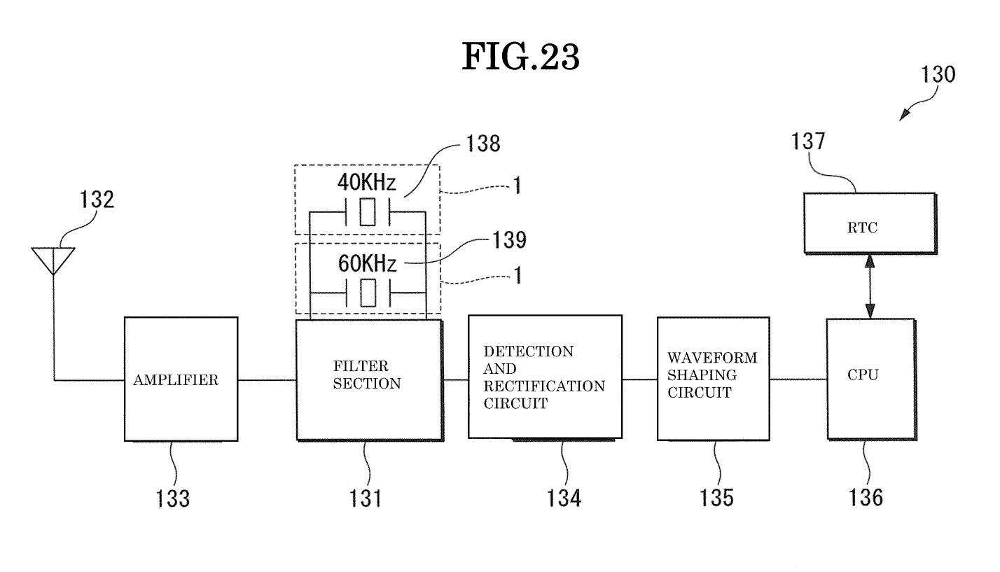

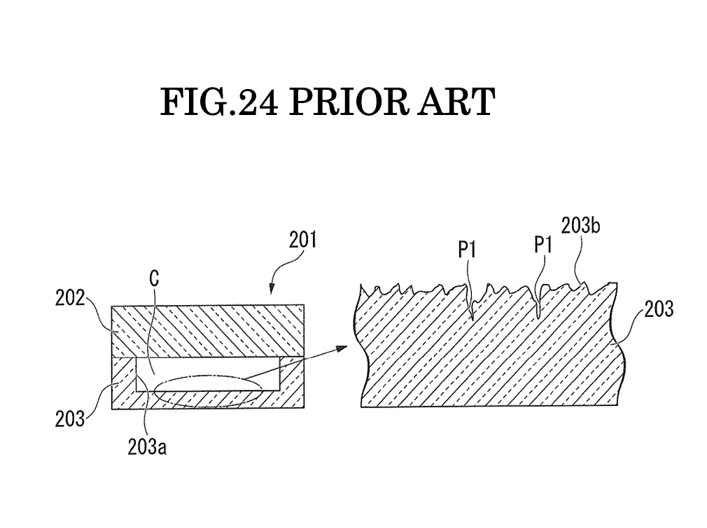

Next, an embodiment of a radio-controlled timepiece related to the present invention will be described with reference to FIG. 23.

As shown in FIG. 23, a radio-controlled timepiece 130 of the present embodiment includes the piezoelectric vibrators 1 electrically connected to a filter section 131, and is a timepiece with a function of receiving a standard radio wave including the timepiece information, automatically changing it to the correct time, and displaying it.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the whole of Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequencies.

In addition, the filtered signal with a predetermined frequency is detected and demodulated by a detection and rectification circuit 134.

Then, the time code is extracted by a waveform shaping circuit 135 and counted by a CPU 136. The CPU 136 reads the information including the current year, the total number of days, the day of the week, the time, and the like. The read information is reflected on an RTC 137, and the correct time information is displayed. Because the carrier wave is 40 kHz or 60 kHz, a vibrator having the tuning fork structure described above is suitable for the crystal vibrator sections 138 and 139.

In addition, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 of the present embodiment includes the high-quality piezoelectric vibrator 1 in which the flexural strength is ensured and the airtightness in the cavity C is reliably ensured and which has an improved yield, the radio-controlled timepiece itself can also similarly have high quality because its electrical conductivity is stably ensured and the reliability of the operation is improved. In addition to this, it is possible to count the time precisely and stably over a long period of time.

In addition, the present invention is not limited to the embodiments described above, and various changes may be made without departing from the spirit and scope of the invention.

For example, although the shapes of the through holes 30 and 31 were formed in a cylindrical shape of a straight sectional shape in the embodiments described above, it is also possible to use a conical shape of a tapered sectional shape.

In addition, in the above embodiment, the piezoelectric vibrating reed 4 with a groove in which the groove 18 was formed on both the surfaces of the vibrating arms 10 and 11 was mentioned as an example of the piezoelectric vibrating reed 4. However, a piezoelectric vibrating reed without the groove 18 may be used. However, since the electric field efficiency between the pair of excitation electrodes 15 can be improved by forming the groove 18 when a predetermined voltage is applied to the pair of excitation electrodes 15, vibration loss can be suppressed. As a result, the vibration characteristic can be further improved. That is, since the CI value (Crystal Impedance) can be further reduced, the performance of the piezoelectric vibrating reed 4 can be further improved. From this point of view, it is preferable to form the groove 18.

In addition, although the tuning fork type piezoelectric vibrating reed 4 was mentioned as an example in the embodiment described above, the present invention is not limited to the tuning fork type. For example, it may be a thickness-shear vibrating reed.

In addition, although the base substrate 2 and the lid substrate 3 are anodically bonded to each other with the bonding film 35 interposed therebetween in the embodiment described above, the present invention is not limited to anodic bonding. However, the anodic bonding is preferable as both the substrates 2 and 3 can be firmly bonded to each other.

In addition, although the piezoelectric vibrating reed 4 was bump-bonded in the above-described embodiment, the present invention is not limited to the bump bonding. For example, the piezoelectric vibrating reed 4 may be bonded using a conductive adhesive. However, since the piezoelectric vibrating reed 4 can be floated from the top surface of the base substrate 2 by bump bonding, a minimum vibration gap required for vibration can be naturally ensured. Therefore, bump bonding is preferable.

The piezoelectric vibrator manufacturing method related to the present invention can be applied to a method of manufacturing a surface mount type (SMD) piezoelectric vibrator in which a piezoelectric vibrating reed is sealed in a cavity formed between two substrates bonded to each other.

What is claimed is:

1. A method of manufacturing a package with a recessed cavity formed in at least one of first and second substrates formed of a glass material, the package manufacturing method comprising:
a cavity forming step of forming the cavity by performing press molding on at least one molded substrate of the first and second substrates; and:
a heat treatment step of heating the molded substrate formed with the cavity.

2. The package manufacturing method according to claim 1,
wherein a polishing step of polishing a surface formed with the cavity is performed after the heat treatment step.

3. The package manufacturing method according to claim 1,
wherein the molded substrate is formed of soda glass, and the temperature in the heat treatment step is equal to or larger than 600° C. and equal to or smaller than 700° C.

4. The package manufacturing method according to claim 3,
wherein the temperature in the heat treatment step is equal to or larger than 670° C. and equal to or smaller than 680° C.

5. A method of manufacturing a piezoelectric vibrator comprising:
a through hole forming step of forming a through hole, which communicates into the cavity, in the package manufactured by the manufacturing method according to claim 1;
a penetration electrode forming step of forming a penetration electrode by disposing a conductive material in the through hole; and
a piezoelectric vibrating reed mounting step of disposing a piezoelectric vibrating reed in the cavity and electrically connecting the piezoelectric vibrating reed and the penetration electrode to each other.

6. An oscillator comprising:
the piezoelectric vibrator manufactured by the manufacturing method according to claim 5, which is electrically connected to an integrated circuit, as a vibrator.

7. An electronic device comprising:
the piezoelectric vibrator manufactured by the manufacturing method according to claim 5 which is electrically connected to a timepiece section.

8. A radio-controlled timepiece comprising:
the piezoelectric vibrator manufactured by the manufacturing method according to claim 5 which is electrically connected to a filter section.
